(19) United States
(12) Patent Application Publication
(10) Pub. No.: US 2006/0222098 A1
(43) Pub. Date: Oct. 5, 2006

(54) Impulse noise gating in DSL systems

(76) Inventors: Hossein Sedarat, San Jose, CA (US); Philip DesJardins, Nevada City, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/377,084

(22) Filed: Mar. 15, 2006

Related U.S. Application Data
(60) Provisional application No. 60/663,314, filed on Mar. 18, 2005.

(51) Int. Cl. H03D 1/04; H04K 1/10

(52) U.S. Cl. 375/260; 375/346

(57) ABSTRACT

Embodiments of methods and apparatuses for gating impulse noise in a communication system are described. In one embodiment, a quality measure of a received signal on a communication channel is not adjusted when corruption by impulse noise in the received signal is detected. In another embodiment, tuning parameters of a DSL modem are not adjusted when corruption by impulse noise in the received signal is detected.

### RELATED APPLICATIONS

This application claims the benefit of U.S. provisional application No. 60/663,314, filed on Mar. 18, 2005.

### TECHNICAL FIELD

The invention relates generally to communication systems and, more particularly, to impulse noise gating in a communication system.

### BACKGROUND

There are various types of interference and noise sources in a multi-carrier communication system, such as a Discrete MultiTone (DMT) system. Interference and noise may corrupt the data-bearing signal on a sub-channel (often referred to as a tone) tone as the signal travels through the communication channel and is decoded at the receiver. The transmitted data-bearing signal may be decoded erroneously by the receiver because of this signal corruption. The number of data bits or the amount of information that a sub-channel carries may vary from sub-channel to sub-channel and depends on the relative power of the data-bearing signal compared to the power of the corrupting signal on that particular sub-channel.

In order to account for potential interference on the transmission line and to guarantee a reliable communication between the transmitter and receiver, each sub-channel of a DMT system is typically designed to carry a limited number of data bits per unit time based on the sub-channel's Signal to Noise Ratio (SNR) using a bit-loading algorithm, which is an algorithm to determine the number of bits to assign to each sub-channel. The number of bits that a specific sub-channel may carry while maintaining a target bit error rate (BER) decreases as the relative strength of the corrupting signal increases, that is when the SNR decreases. Thus, the SNR of a sub-channel may be used to determine how much data should be transmitted on the sub-channel to maintain a target bit error rate.

It is often assumed that the corrupting signal is an additive random source with Gaussian distribution and white spectrum. With this assumption, the number of data bits that each sub-channel can carry relates directly to the SNR. However, this assumption may not be true in many practical cases and there are various sources of interference that do not have a white, Gaussian distribution. Impulse noise is one such noise source. Bit-loading algorithms are usually designed based on the assumption of additive, white, Gaussian noise. With such algorithms, the effects of impulse noise can be underestimated resulting in an excessive rate of error during actual data transmission.

Further, channel estimation procedures that are designed to optimize performance in the presence of stationary impairments such as additive, white, Gaussian noise, are often poor at estimating non-stationary or cyclo-stationary impairments, such as impulse noise. Consequently, Digital Subscriber Line (DSL) modem training procedures are typically well suited to optimizing performance in the presence of additive, white, Gaussian noise, but leave the modem receivers relatively defenseless to impulse noise.

### BRIEF DESCRIPTION OF THE DRAWINGS

One or more embodiments of the invention are illustrated by way of example and not limitation in the figures of the accompanying drawings, in which like references indicate similar elements and in which:

FIG. 1 illustrates a schematic diagram of an embodiment of a DSL system;

FIG. 2 illustrates a schematic diagram of a digital communication system in which an embodiment of the invention can be implemented;

FIG. 3 illustrates a schematic diagram showing an embodiment of a receiver that performs impulse noise gating;

FIG. 4 illustrates a schematic diagram showing an embodiment of a system to perform impulse noise gating; and

FIG. 5 illustrates an embodiment of a method of impulse noise gating in a DSL system.

### DETAILED DISCUSSION

In the following description, for purposes of explanation, numerous specific details are set forth in order to provide a thorough understanding of the invention. It will be evident, however, to one skilled in the art that the invention may be practiced without these specific details. In other instances, well-known circuits, structures, and techniques are not shown in detail or are shown in block diagram form in order to avoid unnecessarily obscuring an understanding of this description. Impulse Noise can be a difficult impairment for DSL modems. Impulse noise with duration of tens of microseconds can cause errors in all the used sub-channels at the receiver. Further, impulse noise can have power bursts that are much higher than the background noise level causing significant performance loss. These power bursts can have a very small duty cycle such that they do not contribute significantly to average noise power. This can result in aggressive bit loading on some or all sub-channels in a DMT system, which would yield a high bit error rate much greater than the target BER.

Impulse noise is a corrupting signal that is typically considered to be difficult to correct and compensate for. For instance, impulse noise can affect and bias the measurements made by a communication system regarding the quality of the received signal. Examples of these measurements include noise power measurements and timing synchronization measurements. Because these measurements are used to adjust, adapt and fine-tune some of the parameters for optimal performance of the communication system, impulse noise can result in non-optimal adaptation of the communication system to changes in the received signal quality.

Embodiments of the invention may relate to any communication system, and, in particular to a multi-carrier system, in which non-Gaussian noise, such as impulse noise, affects a received signal can be beneficial.

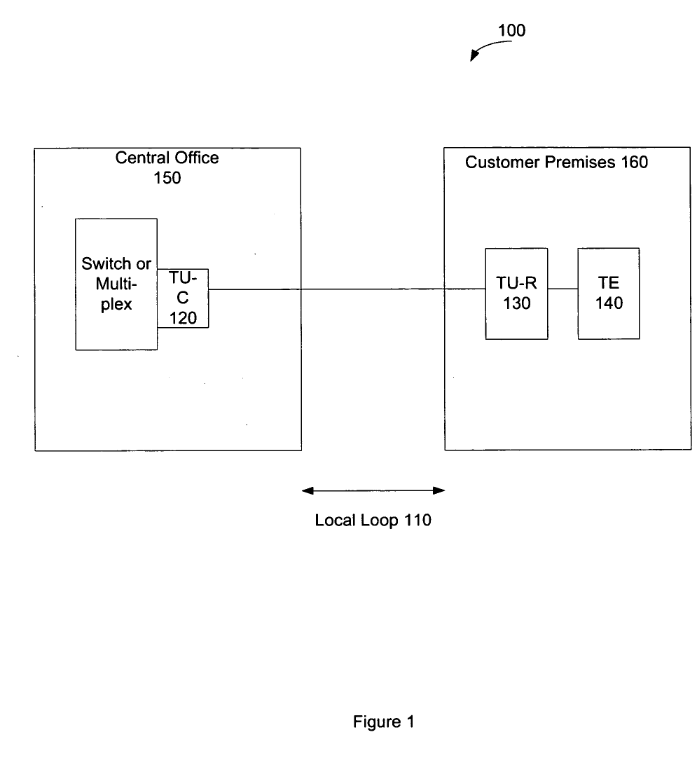

FIG. 1 shows a DSL system 100. The DSL system 100 consists of a local loop 110 (telephone line) with a transceiver (also known as a modem) at each end of the wires. The transceiver at the network end of the line 150 is called transmission unit at the central end (TU-C) 120. The TU-C 120 may reside within a DSL access multiplexer (DSLAM) or a digital loop carrier remote terminal (DLC-RT) for lines fed from a remote site. The transceiver at the customer end 160 of the line is called transmission unit at the remote end (TU-R) 130. FIG. 1 also shows the terminal equipment 140, which is the end-user equipment, such as a personal computer or a telephone.

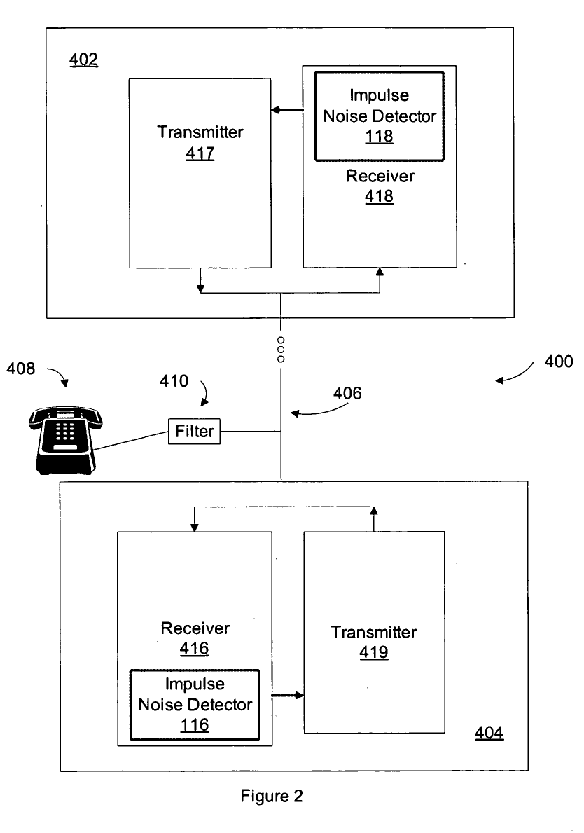

FIG. 2 illustrates a block diagram of an embodiment of a Discrete MultiTone system. The Discrete MultiTone system 400, such as a Digital Subscriber Line (DSL) based network, may have two or more transceivers 402 and 404, such as a DSL modem in a set top box. In one embodiment, the set top box may be a stand-alone DSL modem. In one embodiment, for example, the set top box employs a DSL mode along with other media components to combine television (Internet Protocol TV or Satellite) with broadband content from the Internet to bring commercial video and Internet communications to an end user's TV set. The multi-carrier communication channel may communicate a signal to a residential home. The home may have a home network, such as an Ethernet. The home network may either use the multi-carrier communication signal, directly, or convert the data from the multi-carrier communication signal. The set top box may also include an integrated Satellite and Digital Television Receiver, High-Definition Digital Video Recorder, Digital Media Server and other components.

The first transceiver 402, such as a Discrete MultiTone transmitter, transmits and receives communication signals from the second transceiver 404 over a transmission medium 406, such as a telephone line. Other devices such as telephones 408 may also connect to this transmission medium 406. An isolating filter 410 generally exists between the telephone 408 and the transmission medium 406. A training period occurs when initially establishing communications between the first transceiver 402 and a second transceiver 404.

The Discrete MultiTone system 400 may include a central office, multiple distribution points, and multiple end users. The central office may contain the first transceiver 402 that communicates with the second transceiver 404 at an end user's location.

Each transmitter portion 417, 419 of the transceivers 402, 404, respectively, may transmit data over a number of mutually independent sub-channels i.e., tones. Each sub-channel carries only a certain portion of data through a modulation scheme, such as Quadrature Amplitude Modulation (QAM) of the sub-carrier. The number of information bits loaded on each sub-channel and the size of corresponding QAM constellation may potentially vary from one sub-channel to another and depend generally on the relative power of signal and noise at the receiver. When the characteristics of signal and noise are known for all sub-channels, a bit-loading algorithm may determine the optimal distribution of data bits and signal power amongst sub-channels. Thus, a transmitter portion 417, 419 of the transceivers 402, 404 modulates each sub-carrier with a data point in a QAM constellation.

Each transceiver 402, 404 also includes a receiver portion 418, 416 that contains hardware and/or software in the form of software and/hardware to detect for the presence of impulse noise present in the communication channel. The impulse detector 116, 118 detects the presence of impulse noise in the communication channel over finite intervals of time called time frames (or simply frames).

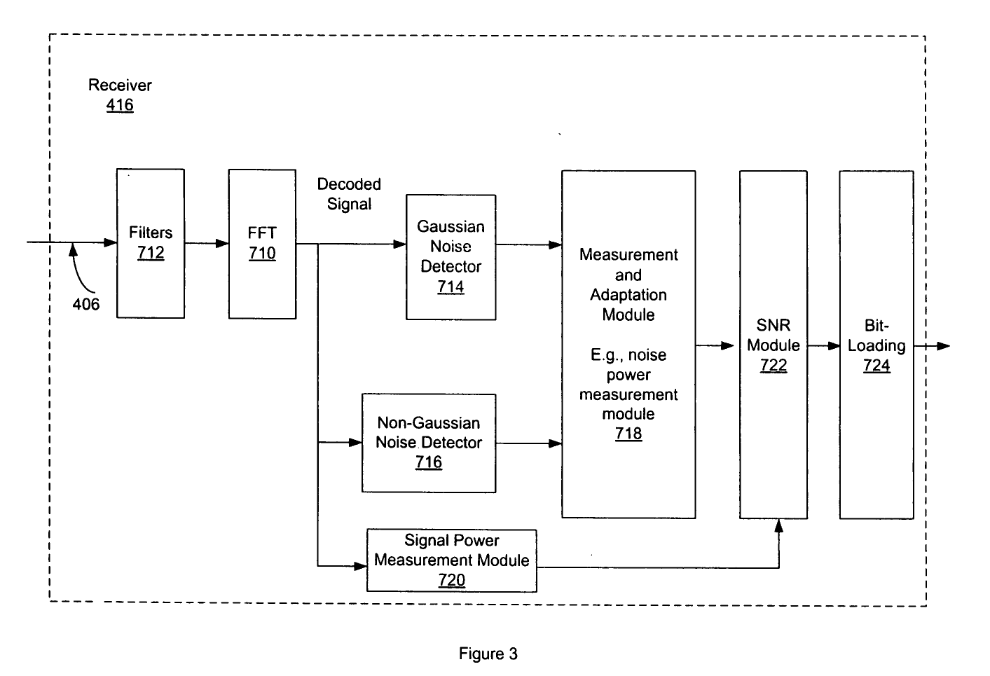

FIG. 3 illustrates one embodiment of a receiver of FIG. 2. In this embodiment, receiver 416 may contain various modules such as a Fast Fourier Transform (FFT) module 710, filters 712, a Gaussian Noise Detector 714, a non-Gaussian Noise Detector 716, a measurement and adaptation module 718, a SNR module 722 and bit-loading module 724. Additional modules and functionality may exist in the receiver 416 that are not illustrated so as not to obscure an understanding of embodiments of the invention. Further, while certain modules and functionality are illustrated to exist in the receiver 416, the modules and functionality may be physically distributed outside the receiver 416. For instance, measurement and adaptation operations of measurement and adaptation module 718 may be implemented in separate modules. Also, it should be noted that the operations of one or more modules may be incorporated into or integrated with other modules.

In the receiver 416, the data for each sub-channel is typically extracted from the time-domain data by taking the Fourier transform of a block of samples from the multi-carrier signal. The Fast Fourier Transform module 710 receives the output of a set of filters 712 which are used to exclude signals from outside the transmission channel's spectrum. The Fast Fourier Transform module 710 transforms the data samples of the multi-carrier signal from the time-domain to the frequency-domain, such that a stream of data for each sub-carrier may be output from the Fast Fourier Transform module 710. Essentially, the Fast Fourier Transform module 710 acts as a demodulator to separate data corresponding to each sub-channel in the multiple tone signals. The output of the FFT 710 is transmitted to a Frequency Domain Equalizer 726, which corrects for gain and phase-shift effects of the transmission channel. These effects are determined at the modem receiver during transmission by comparing the measured signal output from the FFT to expected outputs. The Frequency Domain Equalizer performs a gain and phase correction on each FFT sub-channel output so that each sub-channel is free of gain and phase errors; these correction factors need to be adjusted during data transmission because the transmission channel can slowly change over time. The output of the Frequency Domain Equalizer is sent to a Gaussian noise detector 714, a non-Gaussian noise detector 716 and measurement and adaptation module 718.

During a training session, for example, between the transceiver in a central office (e.g., transceiver 402) and the transceiver at an end user's location (e.g., transceiver 404), the transmitter portion (e.g., transmitter 417) of the transceiver in the central office transmits long sequences that include each of these data points. Over time, a large number of samples are collected for each potential data point.

The Gaussian noise detector 714 measures the power of Gaussian noise in a sub carrier signal. For each particular sub-carrier of the multi-carrier signal, the Gaussian noise detector 714 measures the power level of total noise for that sub-carrier. The Gaussian noise detector 714 includes a decoder module of expected transmitted data points. The Gaussian noise detector module 714 measures Gaussian noise present in the system by comparing the mean difference between the values of the received data to a finite set of expected data points that potentially could be received. The noise in the signal may be detected by determining the distance between the determined transmitted point (a particular amplitude and phase of the sub-carrier for the data frame) the received point to determine the power of the error signal for that sub-carrier at that data frame. The noise present causes the error between the expected known value and the actual received value.

For each particular sub-carrier of the multi-carrier signal, the non-Gaussian noise detector 716 measures the power level of total noise for that sub-carrier including any impulse noise. If non-Gaussian noise is present, then the non-Gaussian noise detector 716 triggers the non-Gaussian noise compensation to provide information about the non-Gaussian noise contribution to the measurement and adaptation module 718 to achieve a more optimal bit rate that may be carried by a sub-channel.

If impulse noise is present, the measurement and adaptation module 718 may generate measurements, e.g., measurements to be used in SNR calculation and subsequent bit-loading algorithm for that sub-channel, such as noise power measurements, timing synchronization measurements and equalizer quality measurement, without using the corrupted samples in the measurements. The measurement and adaptation module 718 may further not use the corrupted data in fine-tuning the parameters of the DSL modem.

The adaptation and monitoring signals produced by the measurement and adaptation module 718 may be fed back in the receiver, e.g., in order to determine the bit-loading algorithm for a sub-channel.

The measurement and adaptation module 718 can also collect and keep track of the statistical information related to impulse noise. This information can be used to characterize the nature of the impulse noise on the line and can provide guidelines on adjusting some of the modem parameters that provide more resilience towards impulse noise. For instance, measurement and adaptation module 718 can identify the duration of impulse noise and its frequency. This data can be used to monitor the quality of the communication channel. It can also be used to set the minimum requirement on the value of noise margin and impulse noise protection.

The noise power, e.g., as measured by the measurement and adaptation module 718, and the signal power, e.g., as measured by signal power measurement module 720, may be input into a Signal-to-Noise Ratio (SNR) block 722. In certain embodiments, the equivalent noise power calculation may include the noise power calculation made by signal noise detector 708. The SNR block determines a signal-to-noise ratio, which is used to determine bit loading 724 for the sub-carrier.

The Signal Power Measurement module 716 measures the signal power for the sub-carrier, and inputs the result into the SNR module 722. The SNR module 722 determines a signal-to-noise ratio using the equivalent noise power provided by the detector 720. The signal-to-noise ratio is provided to bit-loading module 724 to determine bit-loading for all sub-carriers. The bit rate for a sub-channel determined by the bit-loading module may then be transmitted, using transmitter portion 419, to the transceiver 402 (e.g., at a central office) to enable the transmitter 417 of transceiver 402 to know how many bits to use on each sub-channel.

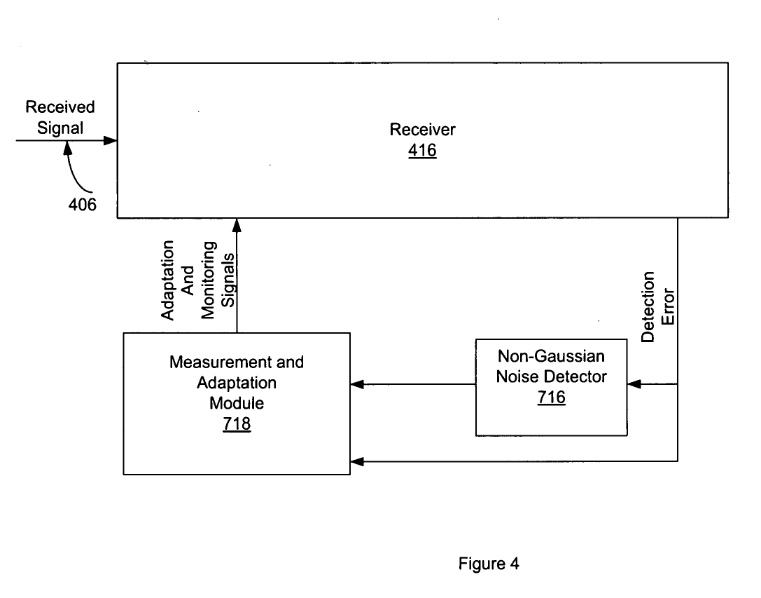

FIG. 4 illustrates another embodiment of a receiver of FIG. 2. In this embodiment, receiver 416 analyzes the received signal to determine an error in the signal transmitted by the transceiver 402 and the signal received by the receiver 416. A non-Gaussian noise detector 716 analyzes the detection error to detect the presence of non-Gaussian noise, such as impulse noise. If such noise is detected, non-Gaussian noise detector 716 may trigger the measurement and adaptation module 718 to prevent an adjustment of a quality measure of the received signal. The non-Gaussian noise detector 716 may trigger the measurement and adaptation module 718 to prevent a tuning of the parameters of the DSL modem. If no impulse noise is detected, the measurement and adaptation module 718 continues to adjust the quality measures (such as noise power measurements, timing synchronization measurements, and equalizer accuracy measurements) and adjust the tuning parameters of the DSL modem.

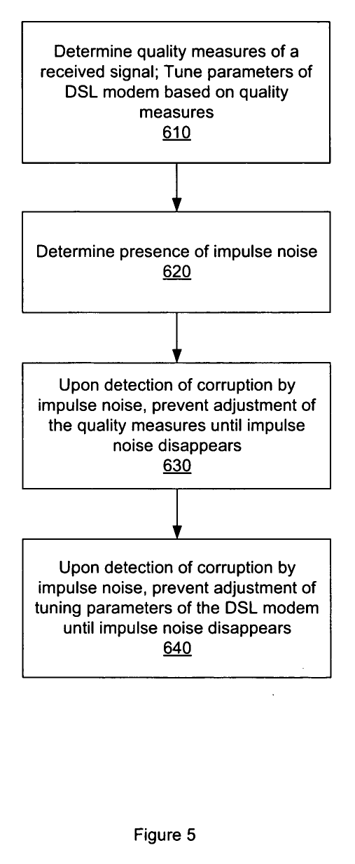

FIG. 5 illustrates an embodiment of a method of impulse noise gating in a DSL system 400. At block 610, a quality measure of a received signal on a communication channel is determined. The quality measure is used to tune one ore more parameters of the DSL modem. At block 620, a presence of non-Gaussian noise including impulse noise in the system is detected or estimated. For instance, a burst of corrupting noise in the received signal may be detected by observing high noise power across several sub-carriers, which is an improbable event with white Gaussian noise. At block 630, an adjustment of a quality measure of the signal based on the detecting of the burst of corrupting noise is prevented. Accordingly, measurement modules in the DSL modem are triggered to prevent them from using the corrupted samples in their measurements, such as noise power measurements, timing synchronization measurements, and equalizer accuracy measurements. At block 640, an adjustment of tuning parameters of the DSL modem based on the detecting of the burst of corrupting noise is prevented. Accordingly, adaptation modules in the DSL modem are triggered to prevent them from using the corrupted samples in their fine-tuning of the parameters of the DSL modem.

Thus, impulse gating may prevent errors in measurements, such as noise power measurements timing synchronization measurements and equalizer accuracy measurements, and allow a better and more stable and more robust adaptation of modem parameters.

Thus, a method for impulse noise gating is described herein. The methods described herein may be embodied on a machine-accessible medium, for example, to perform impulse noise gating. A machine-accessible medium includes any mechanism that provides (e.g., stores and/or transmits) information in a form accessible by a machine (e.g., a computer). For example, a machine-accessible medium includes read only memory (ROM); random access memory (RAM); magnetic disk storage media; optical storage media; flash memory devices; DVD's, electrical, optical, acoustical or other form of propagated signals (e.g., carrier waves, infrared signals, digital signals, EPROMs, EEPROMs, FLASH, magnetic or optical cards, or any type of media suitable for storing electronic instructions. The data representing the apparatuses and/or methods stored on the machine-accessible medium may be used to cause the machine to perform the methods described herein.

Reference in the description to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment. The term “coupled” as used herein may include both directly coupled and indirectly coupled through one or more intervening components.

Although the impulse noise gating methods have been shown in the form of a flow chart having separate blocks and arrows, the operations described in a single block do not necessarily constitute a process or function that is dependent on or independent of the other operations described in other blocks. Furthermore, the order in which the operations are described herein is merely illustrative, and not limiting, as to the order in which such operations may occur in alternate embodiments. For example, some of the operations described may occur in series, in parallel, or in an alternating and/or iterative manner.

While some specific embodiments of the invention have been shown the invention is not to be limited to these embodiments. The invention is to be understood as not limited by the specific embodiments described herein, but only by scope of the appended claims.

What is claimed is:

1. A method, comprising:
determining a quality measure of a received signal on a communication channel; and
preventing an adjustment of the quality measure upon detecting corruption by impulse noise in the received signal.

2. The method of claim 1, further comprising:
preventing a measurement of the received signal from being used in adjusting the quality measure.

3. The method of claim 1, wherein the quality measure includes one or more of a noise power measurement, a timing synchronization measurement and an equalizer accuracy measurement.

4. The method of claim 1, further comprising:
preventing an adjustment of communication parameters upon detecting corruption by impulse noise in the received signal.

5. The method of claim 1, further comprising:
adjusting the quality measure upon a lack of detecting corruption by impulse noise in the received signal.

6. The method of claim 1, further comprising:
determining a signal-to-noise ratio based at least detecting corruption by impulse noise in the received signal; and
performing bit-loading based on the signal-to-noise ratio.

7. An article of manufacture, comprising:
a machine-accessible medium storing instructions that, when executed by a machine, cause the machine to perform operations comprising:
determining a quality measure of a received signal on a communication channel; and
preventing adjustment of the quality measure upon detecting corruption by impulse noise in the received signal.

8. The article of manufacture of claim 7, wherein the data, when accessed by the machine, cause the machine to perform operations further comprising:
preventing a measurement of the received signal from being used in adjusting the quality measure.

9. The article of manufacture of claim 7, wherein the quality measure includes one or more of a noise power measurement, a timing synchronization measurement, and equalizer accuracy measurement.

10. The article of manufacture of claim 7, wherein the data, when accessed by the machine, cause the machine to perform operations further comprising:
preventing adjustment of communication parameters upon detecting corruption by impulse noise in the received signal.

11. The article of manufacture of claim 7, wherein the data, when accessed by the machine, cause the machine to perform operations further comprising:
adjusting the quality measure upon a lack of detecting corruption by impulse noise in the received signal.

12. The article of manufacture of claim 7, wherein the data, when accessed by the machine, cause the machine to perform operations further comprising:
determining a signal-to-noise ratio based at least detecting corruption by impulse noise in the received signal; and
performing bit-loading based on the signal-to-noise ratio.

13. An apparatus, comprising:
a multi-carrier transceiver to detect data in a multi-carrier signal, the transceiver comprising:
a detector module to detect impulse noise in a tone of the multi-carrier signal, and
a measurement and adaptation module coupled to the detector module to determine a quality measure of the multi-carrier signal, wherein the detector module prevents an adjustment of the quality measure by the measurement and adaptation module upon detecting corruption by impulse noise.

14. The apparatus of claim 13, wherein the measurement and adaptation module adjusts parameters of the transceiver, and wherein the detector module is further configured to prevent an adjustment of parameters of the transceiver upon detecting corruption by impulse noise.

15. The apparatus of claim 13, wherein the measurement and adaptation module provides adaptation and monitoring signals to the transceiver.

16. The apparatus of claim 13, wherein the quality measure includes one or more of a noise power measurement, a timing synchronization measurement, and an equalizer accuracy measurement.

17. The apparatus of claim 13, wherein the measurement and adaptation module collects information regarding the impulse noise.

18. The apparatus of claim 13, further comprising:
a signal to noise ratio module coupled to the detector to determine a signal-to-noise ratio based at least detecting corruption by impulse noise in the received signal; and
a bit-loading module coupled to the signal to noise ratio module to determine a bit rate based on the signal-to-noise ratio.

19. A set top box employing a digital subscriber line modem comprising the apparatus of claim 7.
